(19) United States
(12) Patent Application Publication
(10) Pub. No.: US 2008/0042276 A1
(43) Pub. Date: Feb. 21, 2008

(54) System and method for reducing stress-related damage to ball grid array assembly

(76) Inventors: Daryl Carvis Cromer, Cary, NC (US); Tadashi Kosuga, Taga (JP); Howard Jeffrey Locker, Cary, NC (US); Tin-Lup Wong, Chapel Hill, NC (US); Kenshin Yonemochi, Kanagawa-ken (JP)

Correspondence Address: ROGITZ & ASSOCIATES, 750 B STREET, SUITE 3120, SAN DIEGO, CA, 92101, US

(21) Appl. No.: 11/505,777

(22) Filed: Aug. 17, 2006

(51) Int. Cl. H01L 23/48; H01L 23/52; H01L 29/40

(52) U.S. Cl. 257/738

(57) ABSTRACT

A printed circuit board (PCB) for supporting a ball grid array (BGA) includes stress relief features to reduce stress on the solder balls. The stress relief features can be plural lines formed into the PCB along the edges of the BGA, and/or holes formed through the PCB near the corners of the BGA.

### I. FIELD OF THE INVENTION

The present invention relates generally to ball grid array (BGA) assemblies.

### II. BACKGROUND OF THE INVENTION

Ball Grid Assembly (BGA) packages are widely used in cell phone and mobile computers to hold integrated circuit chips onto printed circuit boards (PCB) by means of an array of small solder balls that are disposed on the chip substrate and heated when the chip is placed onto the PCB to effect a solder connection. BGA technology is evolving because continued technology shifts are allowing denser and smaller packaging and product designs. At the same time, changes in government standards are forcing shifts in technologies (e.g., lead free solder) that are reducing the parts resistance to repeated stress cycles (bending, g-forces, vibration, etc). In addition, as product design moves to complex mobile devices, solutions are required to isolate the motherboard and other critical parts in the systems (circuit boards, drives, etc) from these stress factors.

As recognized herein, as BGA packages become smaller they become more susceptible to solder joint damage due to overstress. The damage can be caused by so-called “ECAT” processes, manufacturing and assembly, and customer environment. Minute cracks that develop are not easily detected and require employing expensive electron microscope and destructive tests.

Unfortunately, as understood herein many current chipsets including core I/O chipsets, graphics chips, and processors use BGA packages solely based on electronic pin-out requirements and ignore the needs for structure integrity and reliability in use for mobile devices, which can be subject to considerable shock and stress during transport. Package design with stiffer substrate materials, lead-free solder, smaller BGA solder pitch (0.8 mm to 1.0 mm) and 1200+ solder balls reduces maximum allowable strain or deformation to the printed circuit board, or PCB, hence it is easier to cause overstress to BGA solder joints owing to the direction that the technology is taking.

### SUMMARY OF THE INVENTION

A ball grid array (BGA) assembly has a BGA that includes an integrated circuit chip, a chip substrate supporting the chip, and plural solder balls on the substrate. A printed circuit board (PCB) to which the balls are soldered holds the BGA. Stress relief features are formed in the PCB and are configured and located to reduce stress on at least some solder balls.

In one embodiment, the stress relief features include plural lines formed into the surface of the PCB that faces the BGA, with each line being juxtaposed with a respective edge of the BGA. The lines may be perforations or they may be continuous, and if desired can assume a V-shaped cross-section.

Alternatively, the stress relief features can include plural holes formed in the PCB, with each hole being juxtaposed with a respective corner of the BGA. The holes may be formed completely through the PCB. Both holes and lines may be used.

In another aspect, a printed circuit board (PCB) includes a surface defining a ball grid array (BGA) area having at least three edges and at least three corners onto which a complimentarily-shaped BGA is to be soldered. Stress relief features extend into the PCB and are located just outside of the BGA area.

In yet another aspect, a method for reducing stress on solder balls of a ball grid array (BGA) that is to be soldered to a circuit board (CB) includes cutting and/or drilling plural stress relief features into the CB just outside of an area of the CB to which the BGA is to be mounted.

The details of the present invention, both as to its structure and operation, can best be understood in reference to the accompanying drawings, in which like reference numerals refer to like parts, and in which:

### BRIEF DESCRIPTION OF THE DRAWINGS

FIG. 1 is an exploded perspective view of the BGA and PCB showing a first embodiment of the stress relief features; and

FIG. 2 is an exploded perspective view of the BGA and PCB showing a second embodiment of the stress relief features.

### DETAILED DESCRIPTION OF THE PREFERRED EMBODIMENT

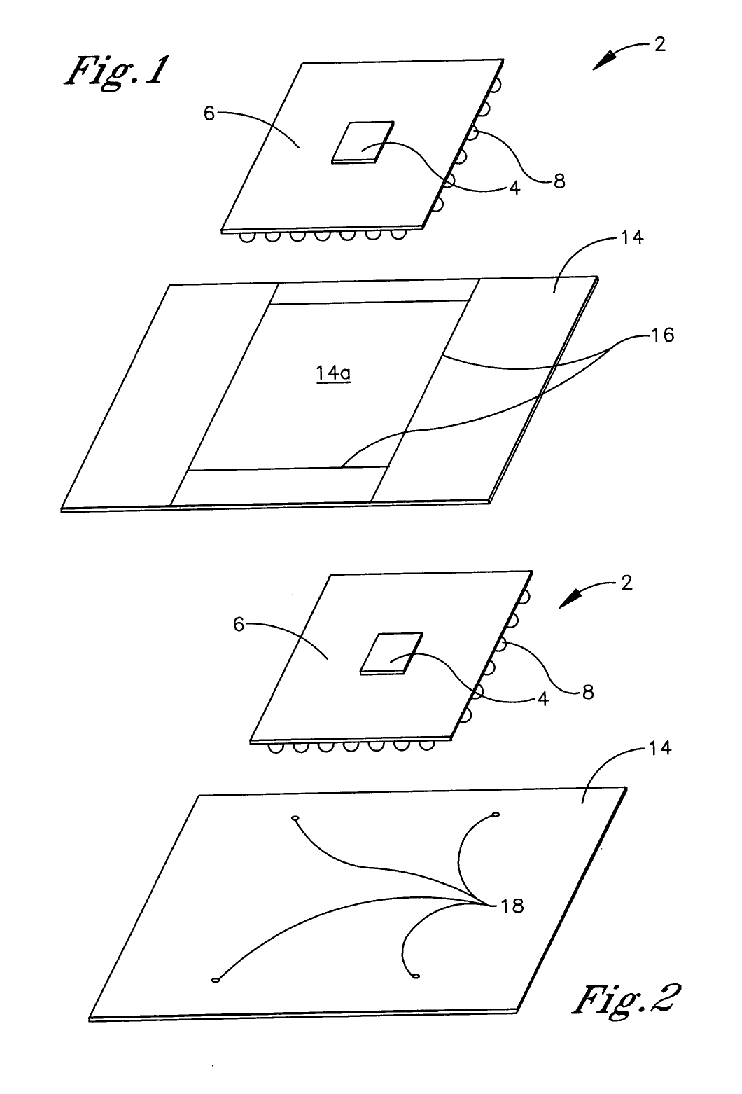

Referring initially to FIG. 1, a ball grid array (BGA) is shown, generally labeled 2. The BGA includes a circuit chip 4 supported on a substrate 6. Plural solder balls 8 are arranged on the underside of the substrate 6. The BGA 2 may be attached a printed circuit board 14, or PCB, by soldering the balls 8 onto the PCB 14 by means of heat. As recognized herein, stress may build up on the soldered balls 8 between the BGA 2 and the PCB 14 and can be lessened by use of the below-described stress relief features that are formed onto the PCB 14.

The BGA 2 defines plural edges, typically four, and engages a surface 14a on the PCB 14 that is reserved for the BGA 2. A stress relief feature, such as one or more grid lines 16, each of which is juxtaposed with a respective edge of the BGA 2 as shown when the BGA 2 is disposed on the surface 14a, may be included on the BGA-designated surface 14a on the PCB 14. As shown in FIG. 1, these lines 16 can be continuous, it being understood that the lines 16 may also be perforations (discontinuous), and may be V-shaped in cross-section. The lines 16 preferably are straight and can be cut, drilled, or otherwise formed into the PCB from the surface 14a by removing material from the PCB, i.e., the thickness of the PCB when measured at the trough of a line 16 is less than the thickness of the PCB when measured at a location between lines. In any case, as can be readily appreciated in reference to FIG. 1 a respective stress relief line 16 preferably is formed in the surface 14a parallel to and just beyond each edge of the BGA 2.

As an alternative to grid lines 16 on the PCB or in addition to them, FIG. 2 illustrates the stress-relieving feature can be established by one or more holes 18 which may be formed in the PCB 14. Preferably, each hole 18 is juxtaposed with a respective corner of the BGA 2, just beyond the corner relative to the periphery of the BGA. The holes 18 may be cut completely through the PCB 14. Additional holes along the edges of the BGA 2 may also be provided. In any case, the stress relief features described herein serve to relieve the solder balls 8 of stress, particularly the solder balls most adjacent to the stress relief features.

While the particular SYSTEM AND METHOD FOR REDUCING STRESS-RELATED DAMAGE TO BALL GRID ARRAY ASSEMBLY is herein shown and described in detail, it is to be understood that the subject matter which is encompassed by the present invention is limited only by the claims.

What is claimed is:

1. A ball grid array (BGA) assembly comprising:
a BGA including an integrated circuit chip, a chip substrate supporting the chip, and plural solder balls on the substrate; and
a printed circuit board (PCB) to which the balls are soldered to hold the BGA onto the PCB, wherein
at least one stress relief feature is formed in the PCB and configured and located to reduce stress on at least some solder balls.

2. The BGA assembly of claim 1, wherein the BGA defines at least three edges and is engaged with a BGA surface of the PCB, and the stress relief feature includes plural lines formed into the BGA surface of the PCB, each line being juxtaposed with a respective edge.

3. The BGA assembly of claim 2, wherein the lines are perforations.

4. The BGA assembly of claim 2, wherein the lines are continuous.

5. The BGA assembly of claim 2, wherein the lines are V-shaped in cross-section.

6. The BGA assembly of claim 1, wherein the BGA defines at least three corners, and the stress relief feature includes plural holes formed in the PCB, each hole being juxtaposed with a respective corner.

7. The BGA assembly of claim 6, wherein the holes are formed completely through the PCB.

8. The BGA assembly of claim 2, wherein the BGA defines at least three corners, and the stress relief feature includes plural holes formed in the PCB, each hole being juxtaposed with a respective corner.

9. A printed circuit board (PCB), comprising:
a surface defining a ball grid array (BGA) area having at least three edges and at least three corners onto which a complimentarily-shaped BGA is to be soldered; and
stress relief features extending into the PCB and located just outside of the BGA area.

10. The PCB of claim 9, wherein the stress relief features include plural lines formed into the surface of the PCB, each line being juxtaposed with a respective edge.

11. The PCB of claim 10, wherein the lines are perforations.

12. The PCB of claim 10, wherein the lines are continuous.

13. The PCB of claim 10, wherein the lines are V-shaped in cross-section.

14. The PCB of claim 9, wherein the stress relief features include plural holes formed in the PCB, each hole being juxtaposed with a respective corner.

15. The PCB of claim 14, wherein the holes are formed completely through the PCB.

16. The PCB of claim 10, wherein the stress relief features include plural holes formed in the PCB, each hole being juxtaposed with a respective corner.

17. A method for reducing stress on solder balls of a ball grid array (BGA) that is to be soldered to a circuit board (CB), comprising:
cutting and/or drilling plural stress relief features into the CB just outside of an area of the CB to which the BGA is to be mounted.

18. The method of claim 17, wherein the BGA defines at least three edges and is engageable with a BGA surface of the CB, and the stress relief features include plural lines formed into the BGA surface of the CB, each line being juxtaposed with a respective edge of the BGA when the BGA is mounted on the CB.

19. The method of claim 17, wherein the BGA defines at least three corners, and the stress relief features include plural holes formed in the CB, each hole being juxtaposed with a respective corner of the BGA when the BGA is mounted on the CB.

20. The method of claim 18, wherein the BGA defines at least three corners, and the stress relief features include plural holes formed in the CB, each hole being juxtaposed with a respective corner of the BGA when the BGA is mounted on the CB.
